(19) United States
(12) Patent Application Publication
(10) Pub. No.: US 2026/0137001 A1
(43) Pub. Date: May 14, 2026

(54) SEMICONDUCTOR PACKAGE

(71) Applicant: Samsung Electronics Co., Ltd., Suwon-si (KR)

(72) Inventors: Keunyoung Lee, Suwon-si (KR); Dongok Kwak, Suwon-si (KR)

(21) Appl. No.: 19/379,064

(22) Filed: Nov. 4, 2025

(30) Foreign Application Priority Data
Nov. 13, 2024 (KR) 10-2024-0161332

(51) Int. Cl. H01L 25/065; H01L 23/00; H01L 23/498

(52) U.S. Cl. CPC H10W 90/00; H10W 90/701; H10W 72/07554; H10W 72/884; H10W 90/24; H10W 90/724; H10W 90/732; H10W 90/734; H10W 90/752

(57) ABSTRACT

A semiconductor package including a substrate including a first opening and a second opening that extend into a bottom surface of the substrate, a chip stack structure on the substrate, a controller chip spaced apart from the chip stack structure in a horizontal direction and on the substrate, a first wiring in the substrate and electrically connecting the chip stack structure to the controller chip, a test pad on the substrate in the first opening, where a surface of the test pad is exposed by the first opening, a second wiring in the substrate and electrically connected to the test pad, a first open wiring exposed by the second opening and connected to the first wiring, and a second open wiring exposed by the second opening and connected to the second wiring, where the first open wiring and the second open wiring are not in direct contact with each other.

### CROSS-REFERENCE TO RELATED APPLICATION

This application is based on and claims priority under 35 U.S.C. §119 to Korean Patent Application No. 10-2024-0161332, filed on November 13, 2024, in the Korean Intellectual Property Office, the disclosure of which is herein incorporated by reference in its entirety.

### FIELD

The inventive concept relates to a semiconductor package, and more specifically, to a semiconductor package including a processor chip and a chip stack structure.

### BACKGROUND

The demand for a portable device has been rapidly increasing in the electronic products market, and thus, miniaturization and weight reduction of electronic components mounted on these electronic products may be needed. In order to reduce the size and weight of electronic components, semiconductor packages mounted on the electronic components must process high quantities of data while becoming increasingly reduced in size.

### SUMMARY

The inventive concept relates to a semiconductor package that may improve the operating characteristics of a substrate based on the connection state of a wiring connected to a test pad within the substrate.

The problems solved by the technical idea of the inventive concept are not limited to the problems described above, and other problems may be clearly understood by one of ordinary skill in the art from the following description.

Aspects of the inventive concept provide a semiconductor package as follows:

According to an aspect of the inventive concept, there is provided a semiconductor package including a substrate including a first opening and a second opening that extend into a bottom surface of the substrate, a chip stack structure on the substrate, a controller chip spaced apart from the chip stack structure in a horizontal direction and on the substrate, a first wiring in the substrate and electrically connecting the chip stack structure to the controller chip, a test pad on the substrate in the first opening, where a surface of the test pad is exposed by the first opening, a second wiring in the substrate and electrically connected to the test pad, a first open wiring exposed by the second opening and electrically connected to the first wiring, and a second open wiring exposed by the second opening and electrically connected to the second wiring, where the first open wiring and the second open wiring are not in direct contact with each other.

According to another aspect of the inventive concept, there is provided a semiconductor package including a substrate including a first opening and a second opening extending into a bottom surface of the substrate and an upper substrate pad on a top surface of the substrate, a chip stack structure including a plurality of semiconductor chips that are stacked in a vertical direction, where ones of the plurality of semiconductor chips are offset from one another in a horizontal direction that intersects the vertical direction, a first wire electrically connecting the chip stack structure to the upper substrate pad, a controller chip spaced apart from the chip stack structure in the horizontal direction and on the substrate, a first wiring in the substrate that electrically connects the first wire to the controller chip through the upper substrate pad, a test pad on the substrate in the first opening, where a surface of the test pad is exposed by the first opening, a second wiring in the substrate and electrically connected to the test pad, a first open wiring exposed by the second opening and electrically connected to the first wiring, a second open wiring exposed by the second opening and electrically connected to the second wiring, and a connection wiring electrically connecting the first open wiring to the second open wiring, where the connection wiring is in direct contact with the first open wiring and the second open wiring in the horizontal direction.

According to another aspect of the inventive concept, there is provided a semiconductor package including a substrate including a first opening and a second opening that extend into a bottom surface of the substrate, an upper substrate pad on a top surface of the substrate, a lower substrate pad on the bottom surface of the substrate, a chip stack structure including a plurality of semiconductor chips that are stacked in a vertical direction, where ones of the plurality of semiconductor chips are offset from one another in a horizontal direction that intersects the vertical direction, a first wire electrically connecting the chip stack structure to the upper substrate pad, a controller chip spaced apart from the chip stack structure in the horizontal direction and on the first substrate, where the controller chip is electrically connected to the upper substrate pad on the substrate through a chip connection bump, a first wiring in the substrate that electrically connects the first wire to the controller chip through the upper substrate pad, a test pad on the substrate in the first opening, where a surface of the test pad is exposed by the first opening, a second wiring in the substrate and electrically connected to the test pad, a third wiring electrically connecting the upper substrate pad to the lower substrate pad, a first open wiring exposed by the second opening and electrically connected to the first wiring, a second open wiring exposed by the second opening and electrically connected to the second wiring, and a connection wiring electrically connecting the first open wiring to the second open wiring, where the connection wiring is in direct contact with the first open wiring and the second open wiring in the horizontal direction, a first plating layer is on at least one surface of the first open wiring and a second plating layer is on at least one surface of the second open wiring, the first plating layer is in direct contact with the connection wiring and the first open wiring, and the second plating layer is in direct contact with the connection wiring and the second open wiring.

### BRIEF DESCRIPTION OF THE DRAWINGS

Embodiments will be more clearly understood from the following detailed description taken in conjunction with the accompanying drawings in which:

FIG. 1 is a cross-sectional view schematically illustrating a semiconductor package according to some embodiments;

FIG. 2 is a bottom view schematically illustrating the semiconductor package according to some embodiments;

FIG. 3 is a cross-sectional view schematically illustrating a semiconductor package according to some embodiments;

FIG. 4 is a bottom view schematically illustrating the semiconductor package according to some embodiments;

FIG. 5 is an enlarged view illustrating some example embodiments of a portion AA of FIG. 1;

FIG. 6 is an enlarged view illustrating some example embodiments of the portion AA of FIG. 1;

FIG. 7 is an enlarged view illustrating some example embodiments of the portion AA of FIG. 1;

FIG. 8 is an enlarged view illustrating some example embodiments of a portion BB of FIG. 2;

FIG. 9 is an enlarged view illustrating some example embodiments of the portion BB of FIG. 2;

FIG. 10 is an enlarged view illustrating some example embodiments of the portion BB of FIG. 2;

FIG. 11 is an enlarged view illustrating some example embodiments of a portion AA' of FIG. 3;

FIG. 12 is an enlarged view illustrating some example embodiments of the portion AA' of FIG. 3;

FIG. 13 is an enlarged view illustrating some example embodiments of a portion BB' of FIG. 4;

FIG. 14 is an enlarged view illustrating some example embodiments of the portion BB' of FIG. 4; and

FIG. 15 is a cross-sectional view schematically illustrating a semiconductor package according to some embodiments.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof will be omitted.

The term "first," "second," or the like used herein may modify various elements regardless of the order and/or priority thereof, and is used only for distinguishing one element from another element, without limiting example embodiments. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” as used herein, refers to electrical and/or physical connection between elements or components and does not preclude the presence of additional elements or components therebetween. The term “cover,” “covering” or the like used herein may specify an element, component or layer that is partially or fully, on, surrounding, overlapping or encasing another element, component, or layer.

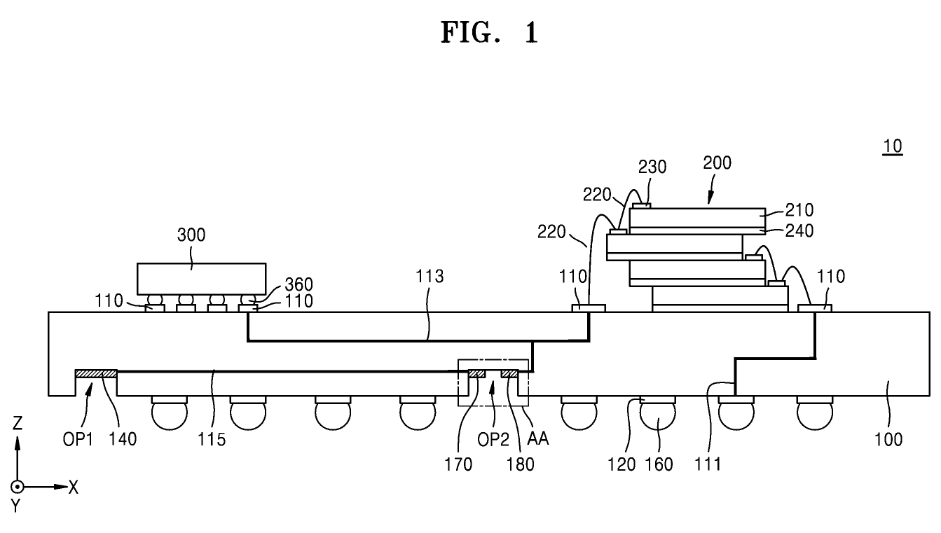

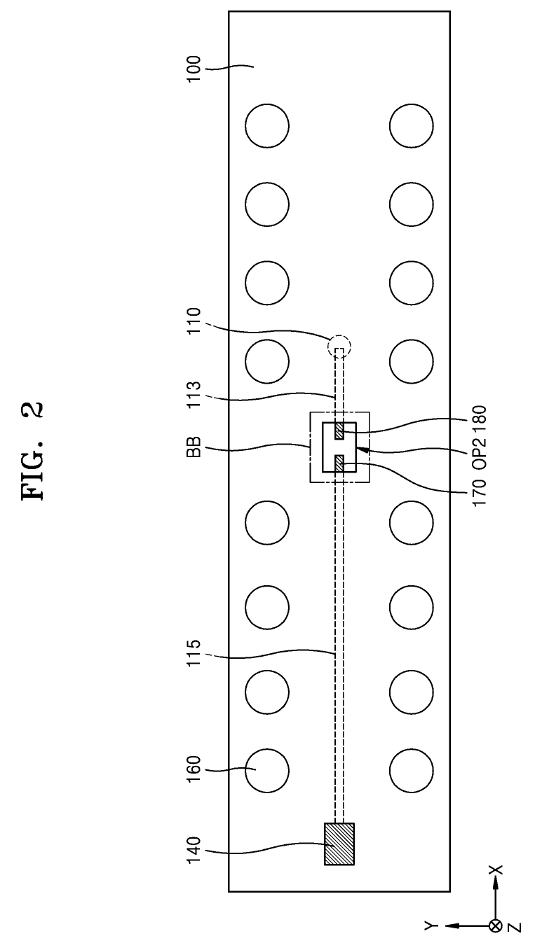

FIG. 1 is a cross-sectional view schematically illustrating a semiconductor package according to some embodiments. FIG. 2 is a bottom view schematically illustrating the semiconductor package according to some embodiments.

Referring to FIGS. 1 and 2, a semiconductor package 10 may include a first substrate 100, a first chip stack structure 200, a controller chip 300, and a test pad 140. As used herein, the first substrate 100 may refer to the substrate 100 and the first chip stack structure 200 may refer to the chip stack structure 200.

The first substrate 100 may be arranged under the first chip stack structure 200 and the controller chip 300, and may be a medium which enables electrical connection of the first chip stack structure 200 to the controller chip 300. According to example embodiments, the first substrate 100 may be formed based on, for example, a ceramic substrate, a printed circuit board (PCB), an organic substrate, an interposer substrate, or the like. In some embodiments, the first substrate 100 may include a redistribution structure.

An X-axis direction X and a Y-axis direction Y indicate a direction parallel to a top surface or a bottom surface of the first substrate 100, and the X-axis direction and the Y-axis direction may be perpendicular to each other. The Z-axis direction Z may indicate a direction perpendicular to a top surface or a bottom surface of the first substrate 100. In other words, the Z-axis direction may be a direction perpendicular to the XY plane.

Furthermore, a first horizontal direction, a second horizontal direction, and a vertical direction may be understood as follows: the first horizontal direction may be understood as an X-axis direction, the second horizontal direction may be understood as a Y-axis direction, and the vertical direction may be understood as a Z-axis direction.

An upper substrate pad 110 may be provided on the top surface of the first substrate 100. The upper substrate pad 110 may be provided in plurality, some of the plurality of upper substrate pads 110 may be connected (i.e., electrically and/or physically) to the first chip stack structure 200, and some of the plurality of upper substrate pads 110 may be connected (i.e., electrically and/or physically) to the controller chip 300. A lower substrate pad 120 may be provided on the bottom surface of the first substrate 100. The lower substrate pad 120 may be provided in plurality. Each of the lower substrate pads 120 may be electrically connected to an external connection terminal 160. In other words, a plurality of lower substrate pads 120 may be electrically connected to a plurality of external connection terminals 160, respectively.

The external connection terminal 160 is arranged under the first substrate 100 and may be electrically connected to the first substrate 100 through the lower substrate pad 120 formed on the bottom surface of the first substrate 100. Specifically, the external connection terminal 160 may be electrically connected to a wiring (e.g. ,third wiring 111) formed in the first substrate 100 through the lower substrate pad 120 attached to the bottom surface of the first substrate 100. Since the external connection terminal 160 is located under the first substrate 100, the top surface of the external connection terminal 160 may be in physical contact with the lower substrate pad 120 attached to the bottom surface of the first substrate 100. The external connection terminal 160 may be electrically connected to an external device, for example, a motherboard, a PCB, a package substrate, etc. Since the external connection terminal 160 is arranged between the external device and the first substrate 100, the bottom surface of the external connection terminal 160 may be physically connected to the external device.

The external connection terminal 160 may be formed of solder balls. However, example embodiments are not limited thereto and the external connection terminal 160 may have a structure including a pillar and solder. The external connection terminal 160 may include at least one of copper (Cu), silver (Ag), gold (Au), and/or tin (Sb).

A first opening OP1 and a second opening OP2 may be formed in the bottom surface of the first substrate 100. The first opening OP1 may have a shape (i.e., hole or recess) extending from the bottom surface of the first substrate 100 upward in the vertical direction Z. The first opening OP1 may be understood as a recess extending from the bottom surface of the first substrate 100 upward in the vertical direction Z. The second opening OP2 may have a shape (i.e., hole or recess) extending from the bottom surface of the first substrate 100 upward in the vertical direction Z. The second opening OP2 may be understood as a recess extending from the bottom surface of the first substrate 100 upward in the vertical direction Z. The first opening OP1 and the second opening OP2 may be spaced apart from each other according to the horizontal direction X and/or the horizontal direction Y (i.e., the first opening OP1 and the second opening OP2 may be spaced apart from each other in the X and/or Y direction). Each of the first opening OP1 and the second opening OP2 may be provided in plurality. According to embodiments, the first opening OP1 and the second opening OP2 may be at substantially the same vertical level (i.e., vertical position or height).

The test pad 140 may be provided in the first opening OP1 of the first substrate 100. The test pad 140 may be exposed on the downward-facing side in the vertical direction Z through the first opening OP1 in the first substrate 100. The test pad 140 may have substantially the same cross-sectional area as that of the first opening OP1.

A first open wiring 180 and a second open wiring 170 may be provided in the second opening OP2. According to some embodiments, the first open wiring 180 may be connected to a first wiring 113, and the second open wiring 170 may be connected to a second wiring 115. The first open wiring 180 and the second open wiring 170 may be provided to be spaced apart from each other in the horizontal direction X and/or the horizontal direction Y. In other words, the first open wiring 180 and the second open wiring 170 may not be connected to each other.

According to some embodiments, the first wiring 113, the second wiring 115, and the third wiring 111 may be formed in the first substrate 100. The first wiring 113 may be a wiring connecting the first chip stack structure 200 with the controller chip 300. In more detail, the first wiring 113 may electrically connect the upper substrate pad 110 connected to the first chip stack structure 200 through the first wire 220 with the upper substrate pad 110 electrically connected to the controller chip 300. In other words, the first wiring 113 may electrically connect the chip stack structure 200 to the controller chip 300 through the upper substrate pad 110 and the first wire 220. The first wiring 113 may be connected to the first open wiring 180. The first open wiring 180 may be electrically connected to the first chip stack structure 200 and the controller chip 300 through the first wiring 113. The first wiring 113 may be a wiring interconnecting the first chip stack structure 200 with the controller chip 300. A portion (i.e., part or section) of the first wiring 113 may be connected to the first open wiring 180. In addition, a portion (i.e., part or section) of the first wiring 113 may be connected to the upper substrate pads 110. A portion or part of the first wiring 113 connecting the first chip stack structure 200 with the controller chip 300 may be connected to the first open wiring 180. The third wiring 111 may connect the lower substrate pad 120 and the upper substrate pad 110. The first wiring 113 and the first open wiring 180 may include the same material. However, in some embodiments, the first wiring 113 and the first open wiring 180 may include different materials.

The second wiring 115 may be connected to the test pad 140. The second wiring 115 may connect the test pad 140 with the second open wiring 170. The second wiring 115 and the second open wiring 170 may include the same material. However, in some embodiments, the second wiring 115 and the second open wiring 170 may include different materials.

The third wiring 111 may be configured to connect the upper substrate pad 110 with the lower substrate pad 120. For example, the third wiring 111 may be configured to connect the upper substrate pad 110 connected to the first chip stack structure 200 through the first wire 220, with the lower substrate pad 120. The first wiring 113 may be configured to connect the upper substrate pad 110 connected to the controller chip 300 through the chip connection bump 360 with the upper substrate pad 110 connected to the chip stack structure 200. The third wiring 111 may not be connected to the first wiring 113 and the second wiring 115. The third wiring 111 may not be connected to the first open wiring 180 and the second open wiring 170.

The first chip stack structure 200 may be arranged on the first substrate 100. The first chip stack structure 200 may include a first semiconductor chip 210, a first semiconductor chip pad 230, and the first wire 220. The first chip stack structure 200 may have a structure in which a plurality of first semiconductor chips 210 are offset-stacked in at least one of a first direction and a second direction (e.g., an X direction and a Y direction). In other words, the first chip stack structure 200 may have a structure in which a plurality of first semiconductor chips 210 are stacked in a cascade type (i.e., a step type) in at least one of the first direction and the second direction (e.g., an X direction and a Y direction).

According to some embodiments, the first direction may be the same as the first horizontal direction X, but is not limited thereto, and the first direction may be a direction (-X direction or negative X direction) opposite to the first horizontal direction X or a direction parallel to the second horizontal direction Y. The second direction may be a direction opposite to the first direction. For example, when the first direction is the first horizontal direction X, the second direction may be understood as the -X direction (i.e., negative X direction).

According to some embodiments, each of the first semiconductor chips 210 may be arranged such that an inactive surface of the semiconductor substrate (i.e., of the first semiconductor chips 210) faces the first substrate 100. That is, a bottom surface of each of the first semiconductor chips 210 may be a surface similar to an inactive surface of the semiconductor substrate (i.e., of the first semiconductor chips), and a top surface of each of the first semiconductor chips 210 may be a surface similar to to an active surface of the semiconductor substrate (i.e., of the first semiconductor chips). In other words, the bottom surface of the first semiconductor chips 210 may be an inactive surface and a top surface of the first semiconductor chips 210 may be an active surface.

According to embodiments, some of the first semiconductor chips 210 of the first chip stack structure 200 may be offset-stacked (i.e., stacked in an offset arrangement) in the first direction, and the remaining others may be offset-stacked in the second direction. For example, as illustrated in FIG. 1, three of the first semiconductor chips 210 may be offset-stacked in order from the bottom in the first direction (e.g., - X direction), and the first semiconductor chip 210 located at the top may be offset-stacked in the second direction (e.g., + X direction).

As the first chip stack structure 200 is stacked in a step type, a portion of the top surface of each of the first semiconductor chips 210 may be exposed. That is, each of the first semiconductor chips 210 may have a portion of the top surface not covered or not overlapped by another first semiconductor chip 210 stacked directly on the top surface thereof. When the first semiconductor chips 210 are stacked in the first direction, portions of top surfaces of the first semiconductor chips 210 in the second direction opposite to the first direction may be exposed. Referring to FIG. 1, the first semiconductor chips 210 are configured such that the three first semiconductor chips 210 in order from bottom to top are offset-stacked in a first direction, and the topmost first semiconductor chip 210 is offset-stacked in a second direction, the two first semiconductor chips 210 in order from bottom to top have top surfaces exposed in the second direction, respectively, and the third stacked first semiconductor chip from bottom has a top surface exposed in the first direction. Here, the second direction may be understood as the + X direction, and the first direction may be understood as the -X direction.

The first semiconductor chip pad 230 may be arranged on a top surface of each of the first semiconductor chips 210. According to embodiments, the first semiconductor chip pad 230 may be arranged on a region in which a portion of the top surface of each of the first semiconductor chips 210 is exposed. According to some embodiments, the first semiconductor chip pad 230 may be provided in plurality. Each of the first semiconductor chip pads 230 may be arranged on an upwardly exposed region of a top surface of each of the plurality of first semiconductor chips 210. According to some embodiments, the plurality of first semiconductor pads 230 may be arranged on top surfaces of the first semiconductor chips 210, respectively. According to some embodiments, the first semiconductor chip pads 230 may be arranged side by side in the second horizontal direction Y on the top surface of the first semiconductor chip 210.

According to some embodiments, the first wire 220 may be formed (i.e., may extend in) in a direction (i.e., a first and/or second direction) in which the first semiconductor chip pad 230 is arranged (i.e., extended). The first wire 220 may be arranged on a top surface exposed upward from the first semiconductor chip 210.

The first wire 220 may be provided in plurality. The first wire 220 may be configured to connect different first semiconductor chip pads 230 with each other. For example, the first wire 220 may connect the first semiconductor chip pads 230 positioned at different vertical levels (i.e., different elevations) with each other. In addition, the first wire 220 may connect the first semiconductor chip pad 230 with the upper substrate pad 110. The plurality of first wires 220 may connect adjacent first semiconductor chips 210 with each other. In addition, the plurality of first wires 220 may be arranged in the second horizontal direction Y to electrically connect the first chip pads 230 having different levels in the vertical direction Z with each other. The first wire 220 may include gold (Au), aluminum (Al), and/or copper (Cu), but is not limited thereto.

An adhesive layer 240 may be positioned between the first substrate 100 and the lowermost first semiconductor chip 210 or between the stacked first semiconductor chips 210 that are adjacent to each other. In some embodiments, the adhesive layer 240 may be a layer configured to attach the first substrate 100 and the lowermost first semiconductor chip 210 to each other or the sequentially stacked first semiconductor chips 210 to each other. Therefore, the first semiconductor chips 210 may be stacked on the first substrate 100 in a stepwise shape and separated by the adhesive layers 240.

For example, the first semiconductor chip 210 located at the lowermost end of the first chip stack structure 200 may be adhered and fixed on the top surface of the first substrate 100 through the adhesive layer 240. The one first semiconductor chip 210 stacked on the top surface of the other first semiconductor chip 210 that is located at the lowermost end (i.e., vertical position relative to the other first semiconductor chips 210) may be adhered and fixed on the top surface of the other first semiconductor chip 210 through the adhesive layer 240. Likewise, the one first semiconductor chip 210 stacked on the other first semiconductor chip 210 may also be adhered and fixed on the top surface of the other first semiconductor chip 210 that is located directly below the one first semiconductor chip 210 through the adhesive layer 240.

The adhesive layer 240 may be a film having its own adhesive properties. For example, the adhesive layer 240 may be a double-sided adhesive film. In some embodiments, the adhesive layer 240 may be a tape-shaped material layer, a liquid-phase coating curing material layer, or a combination thereof. In addition, the adhesive layer 240 may include a thermal setting structure, a thermal plastic structure, a UV curable material, or a combination thereof. The adhesive layer 240 may be referred to as a die attach film (DAF) or a non-conductive film (NCF).

The first semiconductor chip 210 may be a semiconductor chip. According to some embodiments, the first semiconductor chip 210 may be a memory chip or a logic chip. The memory chip may be, for example, a volatile memory chip such as dynamic random access memory (DRAM) or static random access memory (SRAM), or may be a nonvolatile memory chip, such as phase-change RAM (PRAM), magnetoresistive RAM (MRAM), ferroelectric RAM (FeRAM), or resistive RAM (RRAM). In addition, the logic chip may be, for example, a logic chip such as a central processing unit (CPU), a graphics processing unit (GPU), a microprocessor, an application processor (AP), an analog device, or a digital signal processor.

In some embodiments, the first semiconductor chip 210 may be a NAND flash memory chip. Therefore, the first chip stack structure 200 may be a chip stack structure mounted on the first substrate 100 in a structure in which a plurality of NAND flash memory chips is offset-stacked (i.e., stacked in an offset arrangement) in at least one of the first and second directions. In addition to the first chip stack structure 200, another chip stack structure (i.e., additional chip stack structures) may be mounted on the top surface of the first substrate 100. A chip stack structure 200 may include a plurality of semiconductor chips 210 that are stacked in a vertical direction, where ones of the plurality of semiconductor chips 210 are offset from one another in a horizontal direction that intersects the vertical direction.

The controller chip 300 may be mounted on a top surface of the first substrate 100. The controller chip 300 may be adhered to the top surface of the first substrate 100 through the upper substrate pad 110, and the chip connection bump 360. The controller chip 300 may be arranged on the first substrate 100 such that an active surface of the semiconductor substrate (i.e., of the controller chip 300) faces the first substrate 100.

The controller chip 300 may be provided on the first substrate 100 and be spaced apart from the first chip stack structure 200. The controller chip 300 may include an integrated circuit. For example, the controller chip 300 may be a logic chip including a logic circuit. The logic chip may be a controller for controlling memory chips. The controller chip 300 may be a processor chip such as an application specific integrated circuit (ASIC) as a host such as a CPU, a GPU, and a system on chip (SoC).

According to embodiments, the controller chip 300 may be mounted on the first substrate 100 in a flip chip manner through chip connection bumps 360 such as micro-bumps. According to some embodiments, an under-fill material layer surrounding the chip connection bumps 360 may be arranged between the controller chip 300 and the first substrate 100. The under-fill material layer may include, for example, epoxy resin formed in a capillary under-fill method. However, in some embodiments, the molding member 390 may be filled directly into a gap between the controller chip 300 and the first substrate 100 through a molded under-fill process. In this case, the under-fill material layer may be omitted.

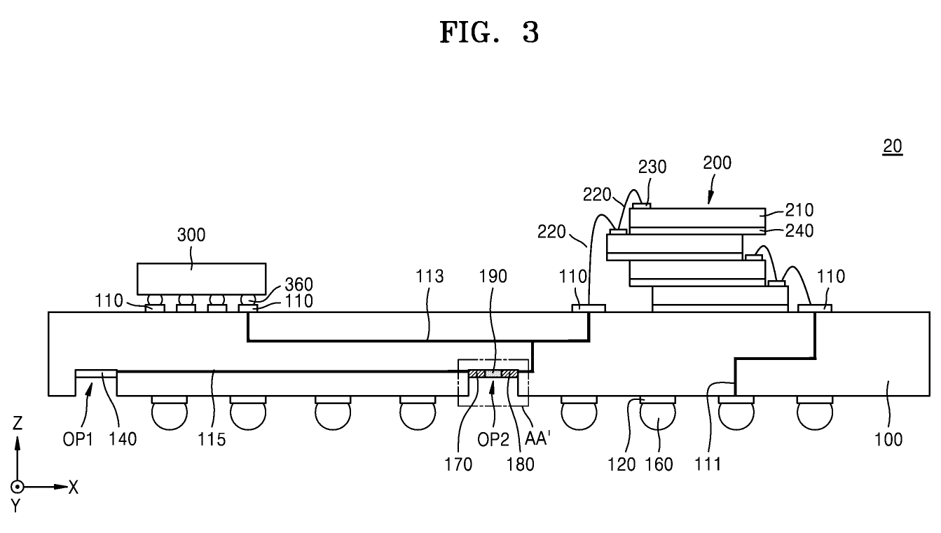

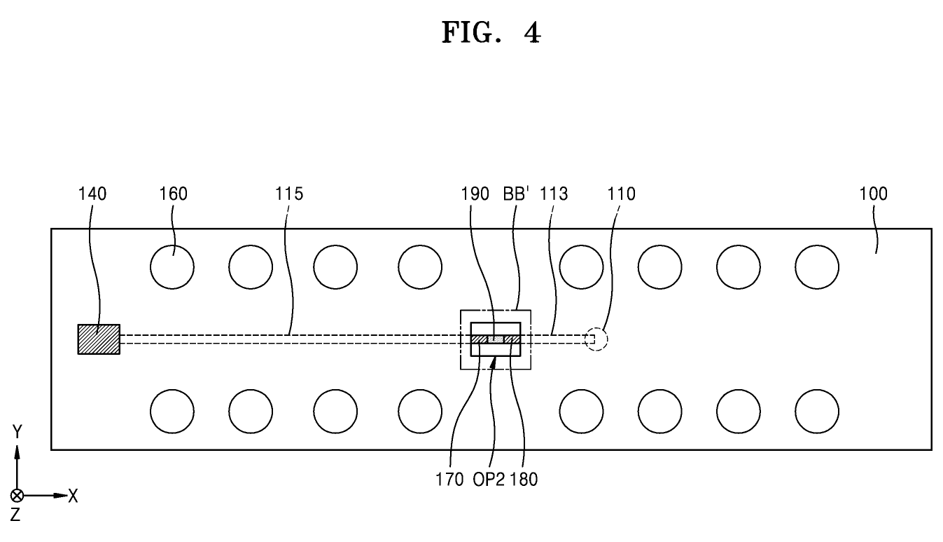

In the semiconductor package 10 according to embodiments, the second wiring 115 connected to the test pad 140 is maintained in a state in which the second wiring 115 is not connected to the first wiring 113. As described below with reference to FIGS. 3 and 4, when a test is required, for example, only when a NAND test or NAND debugging is required, a connection wiring 190 may be selectively formed to connect the second wiring 115 with the first wiring 113. Accordingly, the second wiring 115 may be maintained in a state in which the second wiring 115 is not connected to the first wiring 113, and thus the performance of the first substrate 100 may be improved. Only when a test is required, the first open wiring 180 and the second open wiring 170 may be connected through the connection wiring 190 to transmit a signal flowing through the first wiring 113 to the test pad 140. Accordingly, the performance of the first substrate 100 may be improved.

FIG. 3 is a cross-sectional view schematically illustrating a semiconductor package according to some embodiments. FIG. 4 is a bottom view schematically illustrating the semiconductor package according to some embodiments. Hereinafter, redundant descriptions described with reference to FIGS. 1 and 2 are omitted.

Referring to FIG. 3, a semiconductor package 20 may include a first substrate 100, a first chip stack structure 200, a controller chip 300, and a test pad 140. The semiconductor package 20 may further include a connection wiring 190.

The first substrate 100 may be arranged under the first chip stack structure 200 and the controller chip 300, and may be a medium which enables electrical connection of the first chip stack structure 200 to the controller chip 300. An upper substrate pad 110 may be provided on the top surface of the first substrate 100. The upper substrate pad 110 may be provided in plurality, some of the plurality of upper substrate pads 110 may be connected to the first chip stack structure 200, and some of the plurality of upper substrate pads 110 may be connected to the controller chip 300. A lower substrate pad 120 may be provided on the bottom surface of the first substrate 100. The lower substrate pad 120 may be provided in plurality. Each of the lower substrate pads 120 may be electrically connected to an external connection terminal 160.

A first opening OP1 and a second opening OP2 may be formed in the bottom surface of the first substrate 100. Each of the first opening OP1 and the second opening OP2 may be provided in plurality.

The test pad 140 may be provided in the first opening OP1 of the first substrate 100. A first open wiring 180 and a second open wiring 170 may be provided in the second opening OP2. According to embodiments, the first open wiring 180 may be connected to a first wiring 113, and the second open wiring 170 may be connected to a second wiring 115. The first open wiring 180 and the second open wiring 170 may be spaced apart from each other in the horizontal direction X and/or the horizontal direction Y.

The connection wiring 190 may be provided in the second opening OP2. The connection wiring 190 may connect the first open wiring 180 with the second open wiring 170. According to some embodiments, the connection wiring 190 may be formed by direct printing or nano-printing. The connection wiring 190 may be in contact with each of the first open wiring 180 and the second open wiring 170 in a lateral (i.e., horizontal) direction.

According to some embodiments, the first wiring 113, the second wiring 115, and the third wiring 111 may be formed in the first substrate 100. The first wiring 113 may be a wiring connecting the first chip stack structure 200 with the controller chip 300. Specifically, the first wiring 113 may electrically connect the upper substrate pad 110 connected to the first chip stack structure 200 through the first wire 220 with the upper substrate pad 110 electrically connected to the controller chip 300. The first wiring 113 may be connected to the first open wiring 180. The first open wiring 180 may be electrically connected to the first chip stack structure 200 and the controller chip 300 through the first wiring 113. The first wiring 113 may be a wiring interconnecting the first chip stack structure 200 with the controller chip 300. A portion of the first wiring 113 may be connected to the first open wiring 180. A portion of the third wiring 111 may be connected to the lower substrate pads 120. A portion of the first wiring 113 connecting the first chip stack structure 200 with the controller chip 300 may be connected to the first open wiring 180. A portion of the third wiring 111 may be connected to each of the lower substrate pad 120 and the upper substrate pad 110.

The second wiring 115 may be connected to the test pad 140. The second wiring 115 may connect the test pad 140 with the second open wiring 170. The third wiring 111 may be configured to connect the upper substrate pad 110 with the lower substrate pad 120. The third wiring 111 may not be connected to each of the first open wiring 180 and the second open wiring 170.

The first chip stack structure 200 may be arranged on the first substrate 100. The first chip stack structure 200 may include a first semiconductor chip 210, a first semiconductor chip pad 230, and the first wire 220. The first chip stack structure 200 may have a structure in which a plurality of first semiconductor chips 210 are offset-stacked (stacked in an offset arrangement) in at least one of a first direction and a second direction.

When a test is required in the semiconductor package 10 of FIGS. 1 and 2, the semiconductor package 20 may be understood as forming a connection wiring 190 connecting the first open wiring 180 with the second open wiring 170 in the second opening OP2 through direct printing or nano-printing. Accordingly, the semiconductor package 20 may receive signals required for testing from the first chip stack structure 200 and the controller chip 300 through the test pad 140.

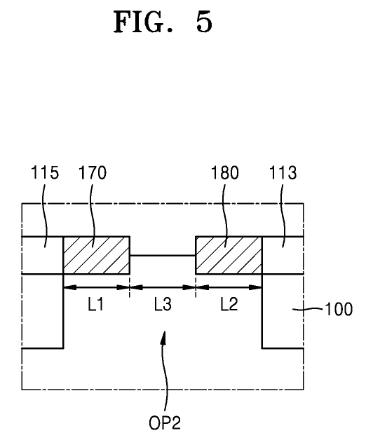

FIG. 5 is an enlarged view illustrating an example of a portion AA of FIG. 1. Hereinafter, redundant descriptions in reference to FIGS. 1,2,3, and 4 are omitted, and differences are mainly described.

Referring to FIG. 5, the first open wiring 180 and the second open wiring 170 may be positioned in the second opening OP2 of the first substrate 100. In addition, the first wiring 113 and the second wiring 115 may be provided in the first substrate 100.

According to some embodiments, the first open wiring 180 and the second open wiring 170 may have substantially the same horizontal length. For example, the horizontal length L2 of the first open wiring 180 may be substantially the same as the horizontal length L1 of the second open wiring 170. In addition, the horizontal distance L3 between the first open wiring 180 and the second open wiring 170 may be substantially the same as each of the horizontal length L2 of the first open wiring 180 and the horizontal length L1 of the second open wiring 170.

In some embodiments, when the ratio of the horizontal length L2 of the first open wiring 180, the horizontal length L1 of the second open wiring 170, and the horizontal distance L3 between the first open wiring 180 and the second open wiring 170 is 1:1:1, the connection wiring 190 may be formed through direct printing described with reference to FIGS. 3 and 4.

According to some embodiments, a vertical cross-section of the second opening OP2 may have a rectangular shape. Accordingly, a vertical cross-section of each of the first open wiring 180 and the second open wiring 170 may also have a rectangular shape.

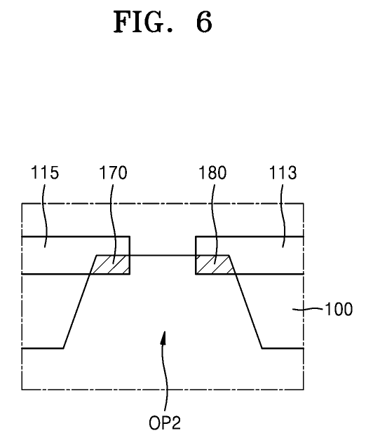

FIG. 6 is an enlarged view illustrating an example embodiment of the portion AA of FIG. 1. Hereinafter, redundant descriptions with reference to FIGS. 1,2,3,4, and 5 are omitted, and differences are mainly described.

Referring to FIG. 6, the first open wiring 180 and the second open wiring 170 may be positioned in the second opening OP2 of the first substrate 100. In addition, the first wiring 113 and the second wiring 115 may be provided in the first substrate 100.

According to some embodiments, a vertical cross-section of the second opening OP2 may have a trapezoidal shape. For example, a vertical cross-section of the second opening OP2 may have a trapezoidal shape in which a horizontal width narrows as a vertical level (i.e., height) increases. When the vertical cross-section of the second opening OP2 has a trapezoidal shape, the vertical cross-section of each of the first open wiring 180 and the second open wiring 170 may also have a trapezoidal shape. In other words, the second opening OP2 may include a tapered recess where the diameter of the recess may decrease in the vertical direction such that the vertical cross section of the second opening OP2 has a trapezoidal shape.

When the vertical cross-section of the second opening OP2 has a trapezoidal shape, direct printing may be facilitated since the first open wiring 180 and the second open wiring 170 are exposed.

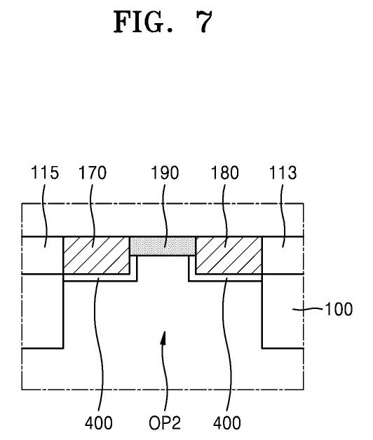

FIG. 7 is an enlarged view illustrating an example embodiment of the portion AA of FIG. 1. Hereinafter, redundant descriptions with reference to FIGS. 1,2,3,4,5, and 6 are omitted, and differences are mainly described.

Referring to FIG. 7, the first open wiring 180 and the second open wiring 170 may be positioned in the second opening OP2 of the first substrate 100. In addition, the first wiring 113 and the second wiring 115 may be provided in the first substrate 100. The connection wiring 190 may electrically and/or physically connect to the first open wiring 180, a first plating layer 400, the second open wiring 170, and a second plating layer 400. The connection wiring 190 may be on or in direct contact with the first and second plating layers 400.

A first surface of the connection wiring 190 may be in direct contact with the first open wiring 180, a second surface of the connection wiring 190 may be in direct contact with the first plating layer 400, the third surface of the connection wiring 190 may be in direct contact with the second open wiring 170 and the second surface of the connection wiring 190 may be in direct contact with the second plating layer 400 such that the first and second plating layers 400 are not in direct contact (i.e., spaced apart from each other). However, example embodiments are not limited thereto. In some embodiments, the first and second plating layers 400 may be electrically and/or physically connected to each other. The first and second plating layers 400 may be on or covering or overlapping a first, second, and/or third surface of the connection wiring 190. The connection wiring 190 may be on the second plating layer 400, adjacent to the second open wiring 170 and may be on the first plating layer 400, adjacent to the first open wiring 180. The first open wiring 180 and the second open wiring 170 may be located on opposite surfaces (e.g., the first and third surface) of the connection wiring 190.

According to some embodiments, a plating layer 400 may cover or overlap surfaces of each of the first open wiring 180 and the second open wiring 170. The plating layer 400 may be configured to prevent oxidation of the first open wiring 180 and the second open wiring 170. The plating layer 400 may completely surround (i.e., cover or be located on) the first open wiring 180 and the second open wiring 170. Accordingly, the first open wiring 180 and the second open wiring 170 may not be exposed by the first substrate 100 and the plating layer 400. According to some embodiments, the plating layer 400 may include nickel, gold, and/or silver.

The plating layer 400 covering, overlapping, or on the first open wiring 180 and the plating layer 400 covering, overlapping or on the second open wiring 170 may not be in contact with each other. The plating layer 400 may be referred to as a plurality of plating layers 400 which may include a first plating layer 400 and a second plating layer 400. Respective ones of a plurality of plating layers 400 may be on at least one surface of the first open wiring 180 and at least one surface of the second open wiring 170, respectively. In other words, a first plating layer 400 may be on at least one surface of the first open wiring 180 and a second plating layer 400 may be on at least one surface of the second open wiring 170. A first plating layer 400 may be in direct contact with the connection wiring 190 and the first open wiring 180, and a second plating layer 400 may be in direct contact with the connection wiring 190 and the second open wiring 170.

Oxidation of the first open wiring 180 and the second open wiring 170 is prevented by the plating layer 400 covering or overlapping each of the first open wiring 180 and the second open wiring 170. Accordingly, when the connection wiring 190 (see FIG. 3) is formed by direct printing later, electrical connection between the first open wiring 180, the connection wiring 190, and the second open wiring 170 may be achieved.

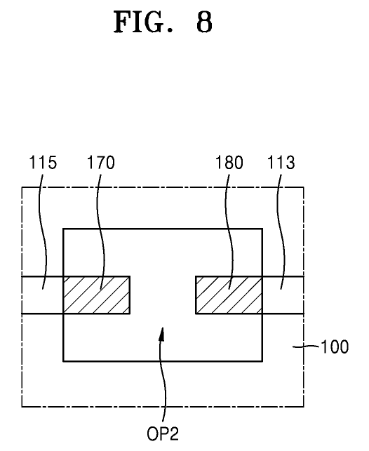

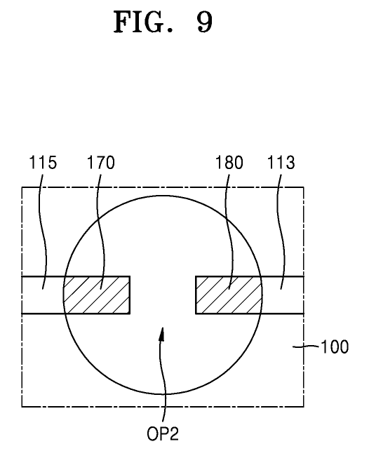

FIG. 8 is an enlarged view illustrating an example of a portion BB of FIG. 2. FIG. 9 is an enlarged view illustrating an example embodiment of the portion BB of FIG. 2. Hereinafter, redundant descriptions with reference to FIGS. 1,2,3,4,5,6, and 7 are omitted, and differences are mainly described.

Referring to FIGS. 8 and 9, the first open wiring 180 and the second open wiring 170 may be positioned in the second opening OP2 of the first substrate 100. In addition, the first wiring 113 and the second wiring 115 may be provided in the first substrate 100. According to some embodiments, a horizontal cross-sectional area of each of the first open wiring 180 and the second open wiring 170 may be in a range of 49 μm² to 2,500 μm².

According to some embodiments, a horizontal cross-section of the second opening OP2 may have a rectangular shape as shown in FIG. 8. According to some embodiments, a horizontal cross-section of the second opening OP2 may have a circular shape as shown in FIG. 9. In addition, the horizontal cross-section of the second opening OP2 is not limited to the shapes described above and may have various shapes.

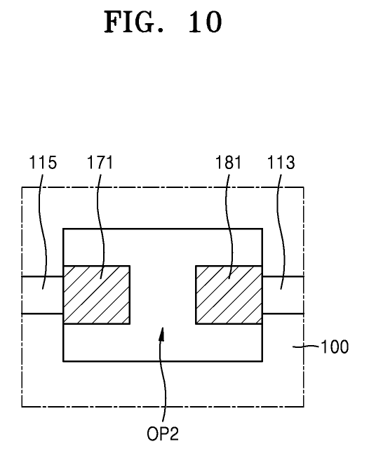

FIG. 10 is an enlarged view illustrating an example of the portion BB of FIG. 2. Hereinafter, redundant descriptions with reference to FIGS. 1,2,3,4,5,6,7,8, and 9 are omitted, and differences are mainly described.

Referring to FIG. 10, a first open wiring 181 and a second open wiring 171 may be positioned in the second opening OP2 of the first substrate 100. In addition, the first wiring 113 and the second wiring 115 may be provided in the first substrate 100.

According to some embodiments, each of the first open wiring 181 and the second open wiring 171 may have a horizontal width greater than that of each of the first wiring 113 and the second wiring 115. For example, the first open wiring 181 may have a horizontal width greater than the horizontal width of the first wiring 113, and the second open wiring 171 may have a horizontal width greater than the horizontal width of the second wiring 115.

Since the first open wiring 181 and the second open wiring 171 have a horizontal width greater than that of each of the first wiring 113 and the second wiring 115, the connection wiring 190 (see FIG. 3) may then be formed through direct printing.

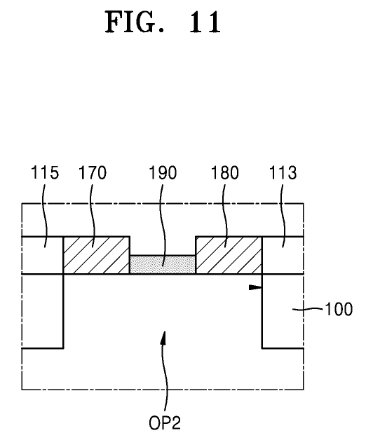

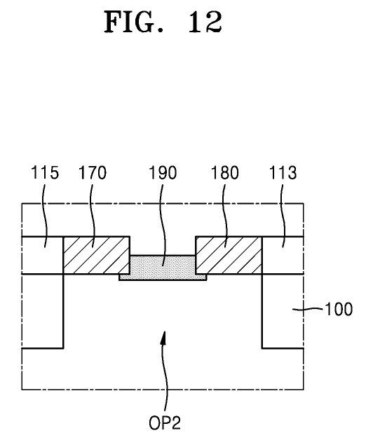

FIG. 11 is an enlarged view illustrating an example of the portion AA' of FIG. 3. FIG. 12 is an enlarged view illustrating another example of the portion AA' of FIG. 3. Hereinafter, redundant descriptions with reference to FIGS. 1, 2, 3, 4, 5, 6, 7, 8, 9 and 10 are omitted, and differences are mainly described.

Referring to FIGS. 11 and 12, the first open wiring 180, the second open wiring 170, and the connection wiring 190 may be positioned in the second opening OP2 of the first substrate 100. The connection wiring 190 may have the same horizontal length as a horizontal length of each of the first open wiring 180 and the second open wiring 170. In addition, the connection wiring 190 may have a different thickness than a thickness of each of the first open wiring 180 and the second open wiring 170. In addition, the first wiring 113 and the second wiring 115 may be provided in the first substrate 100.

The connection wiring 190 may connect the first open wiring 180 with the second open wiring 170. Specifically, the connection wiring 190 may be in contact with each of the first open wiring 180 and the second open wiring 170 in a lateral (i.e., horizontal) direction.

According to some embodiments, the connection wiring 190 may be in contact with the side surfaces of the first open wiring 180 and the second open wiring 170 as illustrated in FIG. 11, and may not be in contact with the lower surfaces of the first open wiring 180 and the second open wiring 170.

According to some embodiments, the connection wiring 190 may be in contact with the side surfaces of the first open wiring 180 and the second open wiring 170 as illustrated in FIG. 12, and may be in contact with some portions of the lower surfaces of the first open wiring 180 and the second open wiring 170. In this case, the vertical level (i.e., elevation) of the lower surface of the connection wiring 190 may be at a lower level than the vertical level (i.e., elevation) of the lower surface of each of the first open wiring 180 and the second open wiring 170. In addition, the connection wiring 190 may partially or completely cover or overlap the surfaces exposed in the first open wiring 180 and the second open wiring 170.

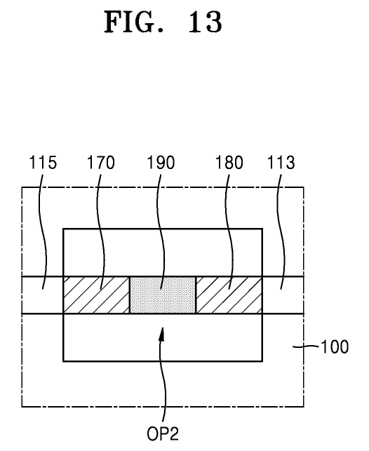

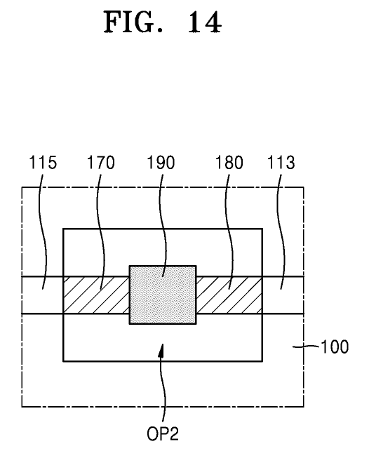

FIG. 13 is an enlarged view illustrating an example of a portion BB' of FIG. 4. FIG. 14 is an enlarged view illustrating an example of the portion BB' of FIG. 4. Hereinafter, redundant descriptions with reference to FIGS. 1, 2, 3, 4, 5, 6, 7, 8, 9, 10, 11 and 12 are omitted, and differences are mainly described.

Referring to FIGS. 13 and 14, the first open wiring 180, the second open wiring 170, and the connection wiring 190 may be positioned in the second opening OP2 of the first substrate 100. In addition, the first wiring 113 and the second wiring 115 may be provided in the first substrate 100.

The connection wiring 190 may connect the first open wiring 180 with the second open wiring 170. Specifically, the connection wiring 190 may be in contact with each of the first open wiring 180 and the second open wiring 170 in a lateral (i.e., horizontal) direction.

According to some embodiments, as shown in FIG. 13, the connection wiring 190 may have the same horizontal width (i.e., horizontal length) as a horizontal width (i.e., horizontal length) of each of the first open wiring 180 and the second open wiring 170.

According to embodiments, as shown in FIG. 14, the connection wiring 190 may have a horizontal width greater than a horizontal width of each of the first open wiring 180 and the second open wiring 170.

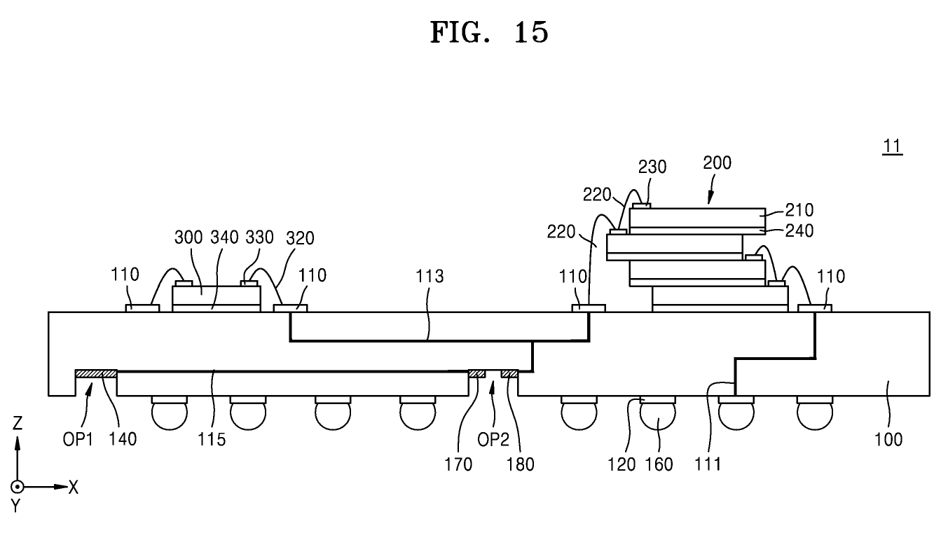

FIG. 15 is a cross-sectional view schematically illustrating a semiconductor package according to some embodiments. Hereinafter, redundant descriptions with reference to FIGS. 1,2,3,4,5,6,7,8,9,10,11,12,13, and 14 are omitted, and differences are mainly described.

Referring to FIG. 15, a semiconductor package 11 may include a first substrate 100, a first chip stack structure 200, a controller chip 300, and a test pad 140.

The first substrate 100 may be arranged under the first chip stack structure 200 and the controller chip 300, and may be a medium which enables electrical connection of the first chip stack structure 200 to the controller chip 300. An upper substrate pad 110 may be provided on the top surface of the first substrate 100. The upper substrate pad 110 may be provided in plurality, some of the plurality of upper substrate pads 110 may be connected to the first chip stack structure 200, and some of the plurality of upper substrate pads 110 may be connected to the controller chip 300. A lower substrate pad 120 may be provided on the bottom surface of the first substrate 100. The lower substrate pad 120 may be provided in plurality. Each of the lower substrate pads 120 may be electrically connected to an external connection terminal 160.

A first opening OP1 and a second opening OP2 may be formed in the bottom surface of the first substrate 100. Each of the first opening OP1 and the second opening OP2 may be provided in plurality.

The test pad 140 may be provided in the first opening OP1 of the first substrate 100. A first open wiring 180 and a second open wiring 170 may be provided in the second opening OP2. According to some embodiments, the first open wiring 180 may be connected to a first wiring 113, and the second open wiring 170 may be connected to a second wiring 115. The first open wiring 180 and the second open wiring 170 may be spaced apart from each other in the horizontal direction X and/or the horizontal direction Y.

The first chip stack structure 200 may be arranged on the first substrate 100. The first chip stack structure 200 may include a first semiconductor chip 210, a first semiconductor chip pad 230, and the first wire 220. The first chip stack structure 200 may have a structure in which a plurality of first semiconductor chips 210 are offset-stacked (i.e., stacked in an offset arrangement) in at least one of a first direction and a second direction.

The controller chip 300 may be mounted on a top surface of the first substrate 100. The controller chip 300 may be adhered onto the top surface of the first substrate 100 through an adhesive layer 340. The controller chip 300 may be provided on the first substrate 100 and be spaced apart from the first chip stack structure 200.

The controller chip 300 may include a controller chip pad 330 and a second wire 320. The controller chip 300 may be electrically connected to the upper substrate pad 110 through the second wire 320. The second wire 320 may electrically connect the controller chip pad 330 with the upper substrate pad 110.

While the inventive concept has been particularly shown and described with reference to embodiments thereof, it will be understood that various changes in form and details may be made therein without departing from the scope of the following claims.

What is claimed is:

1. A semiconductor package comprising:
a substrate including a first opening and a second opening that extend into a bottom surface of the substrate;
a chip stack structure on the substrate;
a controller chip spaced apart from the chip stack structure in a horizontal direction and on the substrate;
a first wiring in the substrate and electrically connecting the chip stack structure to the controller chip;
a test pad on the substrate in the first opening, wherein a surface of the test pad is exposed by the first opening;
a second wiring in the substrate and electrically connected to the test pad;
a first open wiring exposed by the second opening and electrically connected to the first wiring; and
a second open wiring exposed by the second opening and electrically connected to the second wiring,
wherein the first open wiring and the second open wiring are not in direct contact with each other.

2. The semiconductor package of claim 1, wherein the controller chip is electrically connected to an upper substrate pad on the substrate through a chip connection bump.

3. The semiconductor package of claim 1, wherein the controller chip is attached to the substrate through an adhesive layer, and electrically connected to the substrate through a wire.

4. The semiconductor package of claim 1, further comprising a plating layer on at least one surface of each of the first open wiring and the second open wiring.

5. The semiconductor package of claim 1, wherein
a thickness of the first open wiring is greater than a thickness of the first wiring, and
a thickness of the second open wiring is greater than a thickness of the second wiring.

6. The semiconductor package of claim 1, wherein the second opening comprises a tapered recess.

7. The semiconductor package of claim 1, wherein the second opening has a circular cross-section.

8. The semiconductor package of claim 1, wherein
a horizontal length of the first open wiring is between 7 μm and 50 μm, and
a horizontal length of the second open wiring is between 7 μm and50 μm.

9. The semiconductor package of claim 1, wherein a horizontal length of the first open wiring is equal to a horizontal length of the second open wiring.

10. The semiconductor package of claim 9, wherein a horizontal distance between the first open wiring and the second open wiring is equal to the horizontal length of the first open wiring.

11. The semiconductor package of claim 1, wherein a height of the first opening is equal to a height of the second opening with respect to the bottom surface of the substrate.

12. A semiconductor package comprising:
a substrate including a first opening and a second opening extending into a bottom surface of the substrate and an upper substrate pad on a top surface of the substrate;
a chip stack structure including a plurality of semiconductor chips that are stacked in a vertical direction, wherein ones of the plurality of semiconductor chips are offset from one another in a horizontal direction that intersects the vertical direction;
a first wire electrically connecting the chip stack structure to the upper substrate pad;
a controller chip spaced apart from the chip stack structure in the horizontal direction and on the substrate,
a first wiring in the substrate that electrically connects the first wire to the controller chip through the upper substrate pad;
a test pad on the substrate in the first opening, wherein a surface of the test pad is exposed by the first opening,
a second wiring in the substrate and electrically connected to the test pad,
a first open wiring exposed by the second opening and electrically connected to the first wiring;
a second open wiring exposed by the second opening and electrically connected to the second wiring; and
a connection wiring electrically connecting the first open wiring to the second open wiring,
wherein the connection wiring is in direct contact with the first open wiring and the second open wiring in the horizontal direction.

13. The semiconductor package of claim 12, wherein respective ones of a plurality of plating layers are on at least one surface of the first open wiring and at least one surface of the second open wiring, respectively.

14. The semiconductor package of claim 12, wherein a first plating layer is in direct contact with the connection wiring and the first open wiring, and
wherein a second plating layer is in direct contact with the connection wiring and the second open wiring.

15. The semiconductor package of claim 12, wherein a height of a bottom surface of the connection wiring is less than respective heights of each of the first open wiring and the second open wiring with respect to the bottom surface of the substrate.

16. The semiconductor package of claim 12, wherein the second opening comprises a tapered recess.

17. The semiconductor package of claim 12, wherein the controller chip is electrically connected to the upper substrate pad on the substrate through a chip connection bump.

18. A semiconductor package comprising:
a substrate including a first opening and a second opening that extend into a bottom surface of the substrate;
an upper substrate pad on a top surface of the substrate;
a lower substrate pad on the bottom surface of the substrate;
a chip stack structure including a plurality of semiconductor chips that are stacked in a vertical direction, wherein ones of the plurality of semiconductor chips are offset from one another in a horizontal direction that intersects the vertical direction,
a first wire electrically connecting the chip stack structure to the upper substrate pad,
a controller chip spaced apart from the chip stack structure in the horizontal direction and on the first substrate, wherein the controller chip is electrically connected to the upper substrate pad on the substrate through a chip connection bump;
a first wiring in the substrate that electrically connects the first wire to the controller chip through the upper substrate pad,
a test pad on the substrate in the first opening, wherein a surface of the test pad is exposed by the first opening,
a second wiring in the substrate and electrically connected to the test pad,
a third wiring electrically connecting the upper substrate pad to the lower substrate pad;
a first open wiring exposed by the second opening and electrically connected to the first wiring;
a second open wiring exposed by the second opening and electrically connected to the second wiring; and
a connection wiring electrically connecting the first open wiring to the second open wiring,
wherein the connection wiring is in direct contact with the first open wiring and the second open wiring in the horizontal direction,
wherein a first plating layer is on at least one surface of the first open wiring and a second plating layer is on at least one surface of the second open wiring,
wherein the first plating layer is in direct contact with the connection wiring and the first open wiring, and
wherein the second plating layer is in direct contact with the connection wiring and the second open wiring.

19. The semiconductor package of claim 18, wherein
a horizontal length of the first open wiring is between 7 μm and 50 μm, and
a horizontal length of the second open wiring is between 7 μm and 50 μm.

20. The semiconductor package of claim 18, wherein
a thickness of the first open wiring is greater than a thickness of the first wiring, and
a thickness of the second open wiring is greater than a thickness of the second wiring.
